(19) United States
(12) Patent Application Publication
(10) Pub. No.: US 2026/0358712 A1
(43) Pub. Date: Nov. 12, 2026

(54) DEVELOPING METHOD AND SUBSTRATE PROCESSING SYSTEM

(71) Applicant: Tokyo Electron Limited, Tokyo (JP)

(72) Inventor: Yuya KAMEI, Koshi City, Kumamoto (JP)

(73) Assignee: Tokyo Electron Limited, Tokyo (JP)

(21) Appl. No.: 19/487,078

(22) PCT Filed: May 13, 2024
(86) PCT No.: PCT/JP2024/017599

§ 371 Date: Nov. 24, 2025

(30) Foreign Application Priority Data
May 25, 2023 (JP) 2023-085871

(51) Int. Cl. G03F 7/32; B08B 3/08; B08B 7/00; B08B 7/04; C11D 3/43; G03F 7/00; G03F 7/30; G03F 7/40

(52) U.S. Cl. CPC G03F 7/325; B08B 3/08; B08B 7/0057; B08B 7/0071; B08B 7/04; C11D 3/43; G03F 7/3021; G03F 7/40; G03F 7/7075; G03F 7/70991

(57) ABSTRACT

A developing method of performing a development processing on a substrate includes supplying a developing liquid containing an organic solvent to the substrate having a metal-containing coating film exposed into a predetermined pattern; and supplying a first cleaning liquid containing an organic solvent to the substrate supplied with the developing liquid. The first cleaning liquid has a lower solubility for the metal-containing coating film than the developing liquid and contains 0.25 to 50 vol % pure water.

### TECHNICAL FIELD

The various aspects and embodiments described herein pertain generally to a developing method and a substrate processing system.

### BACKGROUND

Patent Document 1 discloses a developing method including a process of supplying a developing liquid containing an organic solvent to a substrate having a metal-containing coating film exposed into a predetermined pattern, and a process of supplying a cleaning liquid containing an organic solvent to the substrate supplied with the developing liquid. In the process of supplying the cleaning liquid in the developing method, the cleaning liquid having a solubility for the metal-containing coating film lower than that of the developing liquid is used.

### PRIOR ART DOCUMENT

Patent Document 1: Japanese Patent Laid-open Publication No. 2022-096081

### DISCLOSURE OF THE INVENTION

### Problems to be Solved by the Invention

The present disclosure provides a technique enabling reduction of residue on a front surface of a substrate generated during development processing of a metal-containing coating film.

### Means for Solving the Problems

In one exemplary embodiment, a developing method of performing a development processing on a substrate includes supplying a developing liquid containing an organic solvent to the substrate having a metal-containing coating film exposed into a predetermined pattern; and supplying a first cleaning liquid containing an organic solvent to the substrate supplied with the developing liquid. The first cleaning liquid has a lower solubility for the metal-containing coating film than the developing liquid and contains 0.25 to 50 vol % pure water.

### Effects Of The Invention

According to the present disclosure, it is possible to reduce the amount of residue on the front surface of the substrate generated during the development processing of the metal-containing coating film.

### BRIEF DESCRIPTION OF THE DRAWINGS

FIG. 1 is a plan view schematically illustrating an internal configuration of a substrate processing system according to an exemplary embodiment.

FIG. 2 is a front side view schematically illustrating the internal configuration of the substrate processing system of FIG. 1.

FIG. 3 is a rear side view schematically illustrating the internal configuration of the substrate processing system of FIG. 1.

FIG. 4 is a longitudinal cross-sectional view schematically illustrating a configuration of a developing liquid supply apparatus according to the exemplary embodiment.

FIG. 5 is a longitudinal cross-sectional view schematically illustrating a configuration of a cleaning liquid supply apparatus according to the exemplary embodiment.

FIG. 6 is a longitudinal cross-sectional view schematically illustrating a configuration of a thermal processing apparatus according to the exemplary embodiment.

FIG. 7 is a longitudinal cross-sectional view schematically illustrating a configuration of an ultraviolet radiation apparatus according to the exemplary embodiment.

FIG. 8A to FIG. 8G are explanatory diagrams illustrating states of a resist film on a wafer during respective processes of a developing method according to the exemplary embodiment.

FIG. 9 is an explanatory diagram illustrating exposed portions and unexposed portions of a metal-containing resist film.

### DETAILED DESCRIPTION

In a manufacturing process of a semiconductor device, a photolithography process is performed. The photolithography process includes a formation of a resist film by resist coating on a semiconductor wafer (hereinafter, described as a “wafer”), an exposure of the resist film, and a formation of a resist pattern by developing the exposed resist film. It is known that in the photolithography process, a metal-containing resist liquid is used to form a metal-containing resist film on the wafer to obtain a finer resist pattern.

When the metal-containing resist film is exposed, a polymerization reaction between metal atoms and oxygen atoms occurs in an exposed portion and does not occur in an unexposed portion. A polymerization reaction portion hardly dissolves in a developing liquid. Thus, during development processing after the exposure, only the unexposed portion is dissolved by the developing liquid supplied to the wafer so that a predetermined pattern is formed on the wafer.

Herein, the unexposed portion is basically a region where a polymerization reaction does not occur. However, in a region near a boundary with the exposed portion, exposure to a small amount of light may generate an intermediate polymer that is hardly soluble in the developing liquid. In the unexposed portion where the intermediate polymer has been formed, when the developing liquid is supplied during the development processing, a part of the intermediate polymer is not dissolved in the developing liquid and residue such as resist scum remains on the wafer.

Since the residue on the wafer causes pattern defects, it is desirable to reduce the amount of residue. In the developing method described in Patent Document 1, the cleaning liquid having the solubility for the metal-containing resist film lower than that of the developing liquid is supplied to the wafer in order to dissolve the residue without dissolving the pattern. However, there is still room for improvement in terms of reducing the amount of residue.

The technique according to the present disclosure enables the reduction of the residue on the front surface of the substrate generated during the development processing of the metal-containing coating film.

Hereinafter, a developing method and a substrate processing system for performing the developing method according to the present exemplary embodiment will be described with reference to the accompanying drawings. Further, in the present disclosure and drawings, parts having substantially the same functions and configurations will be assigned same reference numerals, and redundant description thereof will be omitted.

### (Substrate Processing System)

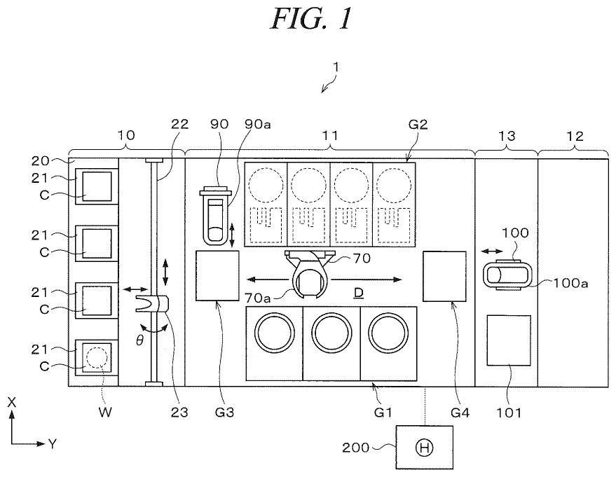

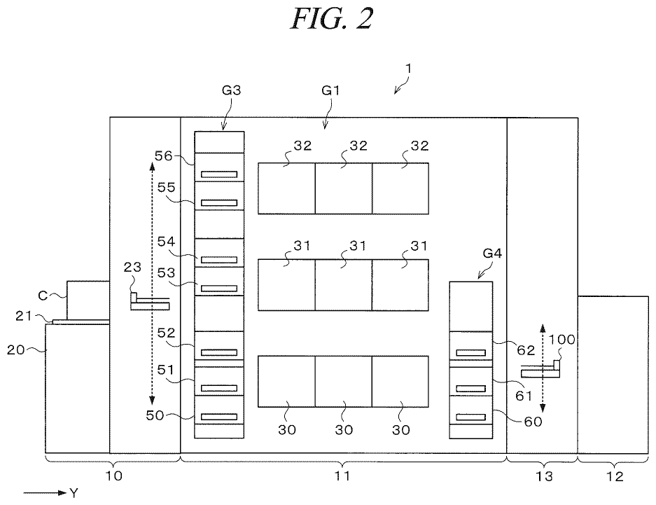

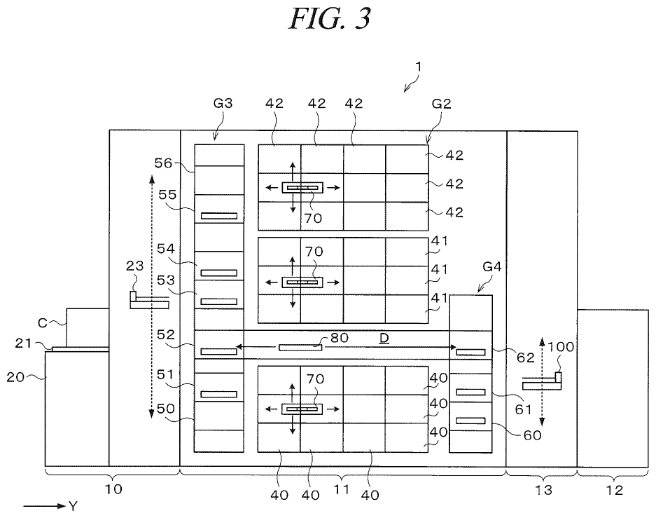

First, a substrate processing system configured to perform a developing method to be described later will be explained. FIG. 1 is a plan view schematically illustrating an internal configuration of a substrate processing system according to the present exemplary embodiment. FIG. 2 and FIG. 3 are schematic front side and rear side views illustrating the internal configuration of the substrate processing system of FIG. 1.

As illustrated in FIG. 1 to FIG. 3, the substrate processing system 1 has a cassette station 10 into/from which a cassette C accommodating therein a plurality of wafers W as substrates is transferred, and a processing station 11 equipped with a plurality of various processing apparatuses which perform predetermined processings on the wafer W. The substrate processing system 1 has a configuration in which the cassette station 10, the processing station 11, and an interface station 13 which is provided adjacent to the processing station 11 and delivers the wafer W to/from an exposure apparatus 12 are integrally connected.

In the cassette station 10, a cassette placement table 20 is provided. A plurality of cassette placement plates 21 is provided on the cassette placement table 20. On the plurality of cassette placement plates 21, the cassettes C are mounted when the cassettes C are transferred to/from the outside of the substrate processing system 1.

In the cassette station 10, a wafer transfer device 23 is provided. The wafer transfer device 23 is movable on a transfer path 22 extending in an X-direction in FIG. 1. The wafer transfer device 23 is also movable in a vertical direction and around a vertical axis (in a θ-direction), and can transfer the wafer W between the cassette C on each of the cassette stage plates 21 and a delivery module in a third block G3 in the processing station 11.

In the processing station 11, a plurality of blocks, for example, four blocks G1, G2, G3 and G4, each including various apparatuses, is provided. For example, the first block G1 is provided on a front side (negative X-axis side in FIG. 1) in the processing station 11, and the second block G2 is provided on the rear side (positive X-axis side in FIG. 1) in the processing station 11. Further, the third block G3 is provided on the cassette station 10 side (negative Y-axis side in FIG. 1) in the processing station 11, and the fourth block G4 is provided on the interface station 13 side (positive Y-axis side in FIG. 1) in the processing station 11.

As shown in FIG. 2, in the first block G1, liquid processing apparatuses, for example, developing liquid supply apparatuses 30, resist coating apparatuses 31, and cleaning liquid supply apparatuses 32 are provided. The liquid processing apparatuses 30 to 32 are disposed in a horizontal direction at different heights from one another.

The developing liquid supply apparatus 30 is configured to supply the developing liquid to the wafer W to perform a development processing thereon. The resist coating apparatus 31 is configured to supply a resist liquid containing a metal (for example, Sn) as a metal-containing coating liquid to the wafer W to form a metal-containing resist film as a metal-containing coating film on the wafer W. The resist coating apparatuses 31 is configured to discharge the resist liquid onto the wafer W through a nozzle and rotates the wafer W to diffuse the resist liquid over the front surface of the wafer W. The cleaning liquid supply apparatus 32 is configured to supply a first cleaning liquid containing an organic solvent to the wafer W to clean the wafer W. The numbers and the arrangement of the developing liquid supply apparatuses 30, resist coating apparatuses 31, and cleaning liquid supply apparatuses 32 can be arbitrarily selected.

In each of the developing liquid supply apparatuses 30, the resist coating apparatuses 31, and the cleaning liquid supply apparatuses 32, for example, spin coating using a predetermined processing liquid or coating liquid is performed on the wafer W. During the spin coating, the processing liquid or coating liquid is discharged onto the wafer W, for example, through a nozzle and the wafer W is rotated to diffuse the processing liquid or coating liquid over the front surface of the wafer W.

As shown in FIG. 3, in the second block G2, thermal processing apparatuses 40, periphery exposure apparatuses 41, and ultraviolet radiation apparatuses 42 are provided in both the vertical and horizontal directions. The thermal processing apparatus 40 is configured to perform a thermal processing such as heating or cooling of the wafer W. The periphery exposure apparatus 41 is configured to expose an outer peripheral portion of the wafer W. The ultraviolet radiation apparatus 42 is configured to radiate ultraviolet light to the wafer W. The numbers and the arrangement of the thermal processing apparatuses 40, periphery exposure apparatuses 41, and ultraviolet radiation apparatuses 42 can be arbitrarily selected.

In the third block G3, a plurality of delivery modules 50, 51, 52, 53, 54, 55 and 56 is provided in this order from the bottom. Further, in the fourth block G4, a plurality of delivery modules 60, 61 and 62 is provided in this order from the bottom.

As shown in FIG. 1 and FIG. 3, in a region surrounded by the first block G1 to the fourth block G4, a wafer transfer region D is provided. In the wafer transfer region D, a wafer transfer device 70 is provided.

Each wafer transfer device 70 has a transfer arm 70a movable, for example, in the X-direction, Y-direction, θ-direction, and vertical direction. A plurality of wafer transfer devices 70 is arranged in the vertical direction, and each of the wafer transfer devices 70 can move in the wafer transfer region D and transfer the wafer W to a predetermined apparatus located at substantially the same height in each of the blocks G1 to G4.

Further, in the wafer transfer region D, a shuttle transfer device 80 is provided. The shuttle transfer device 80 linearly transfers the wafer W between the third block G3 and the fourth block G4.

The shuttle transfer device 80 is configured to be linearly movable, for example, in the Y-direction in FIG. 3. The shuttle transfer device 80 can move in the Y-direction while supporting the wafer W to transfer the wafer W between the delivery module 52 in the third block G3 and the delivery module 62 in the fourth block G4.

As shown in FIG. 1, a wafer transfer device 90 is provided adjacent to the third block G3 on the positive X-axis side. The wafer transfer device 90 has a transfer arm 90a movable, for example, in the X-direction, 0-direction, and vertical direction. The wafer transfer device 90 can move in the vertical direction while supporting the wafer W to transfer the wafer W to each of the delivery modules 50 to 56 in the third block G3.

In the interface station 13, a wafer transfer device 100 and a delivery module 101 are provided. The wafer transfer device 100 has a transfer arm 100a movable, for example, in the Y-direction, θ-direction, and vertical direction. The wafer transfer device 100 can support the wafer W by means of, for example, the transfer arm 100a and transfer the wafer W to/from each of the delivery modules 60 to 62 in the fourth block G4, the delivery module 101 in the interface station 13, and the exposure apparatus 12.

The substrate processing system 1 is equipped with at least one controller 200 as shown in FIG. 1. The controller 200 is configured to process computer-executable instructions that cause the substrate processing system 1 to execute various processes described in the present disclosure. The controller 200 may be configured to control each component of the substrate processing system 1 to execute the various processes described herein. In the exemplary embodiment, a part or all of the controller 200 may be included in the substrate processing system. The controller 200 may include a processor, a storage, and a communication interface. The controller 200 is implemented by, for example, a computer. The processor may be configured to read from the storage a program which provides a logic or routine making it possible to perform various control operations, and execute the read program to thereby perform the various control operations. This program may be stored in the storage in advance, or acquired via a medium when necessary. The acquired program is stored in the storage, read from the storage, and executed by the processor. The medium may be various computer-readable recording medium H or may be a communication line connected to the communication interface. The recording medium H may be a transitory one or a non-transitory one. The processor may be a CPU (Central Processing Unit) or may be one or more circuits. The storage may include a RAM (Random Access Memory), a ROM (Read Only Memory), an HDD (Hart Disk Drive), an SSD (Solid State Drive), or a combination thereof. The communication interface may communicate with the substrate processing system 1 via a communication line such as a LAN (Local Area Network).

The schematic configuration of the substrate processing system 1 has been described. Hereinafter, a schematic configuration of each of the developing liquid supply apparatus 30, the cleaning liquid supply apparatus 32, the thermal processing apparatus 40, and the ultraviolet radiation apparatus 42 included in the substrate processing system 1 according to the present exemplary embodiment will be described in sequence.

### <Developing Liquid Supply Apparatus>

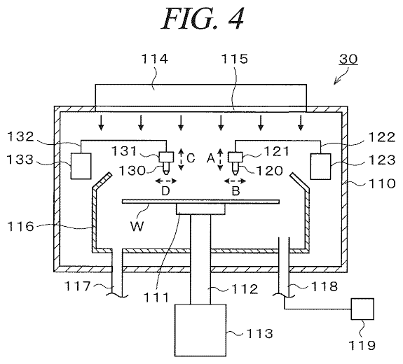

FIG. 4 is a longitudinal cross-sectional view schematically illustrating a configuration of the developing liquid supply apparatus 30 according to the present exemplary embodiment. The developing liquid supply apparatus 30 has a processing vessel 110, and a carry-in/out port (not shown) for the wafer W as the substrate is provided at a side surface of the processing vessel 110. In the processing vessel 110, a spin chuck 111 is provided as a substrate holder. The spin chuck 111 horizontally holds the wafer W, and is connected to a rotator 112 movable in the vertical direction. The rotator 112 is connected to a rotation driver 113 composed of a motor or the like. Accordingly, the wafer W held on the spin chuck 111 is rotated by operating the rotation driver 113.

At a ceiling portion of the processing vessel 110, a filter device 114 is provided. Air purified by the filter device 114 is supplied into the processing vessel 110 via an air supply 115, and a downflow of the purified air is formed in the processing vessel 110.

A cup 116 is provided around the spin chuck 111. The cup 116 is configured to receive and collect a liquid scattered or dropped from the wafer W. At a bottom of the cup 116, a drain pipe 117 and an exhaust pipe 118 are provided. The exhaust pipe 118 leads to an exhaust device 119 such as an exhaust pump.

In the processing vessel 110, a developing liquid nozzle 120 as a developing liquid supply is provided. The developing liquid nozzle 120 is configured to discharge the developing liquid toward the front surface of the wafer W. The developing liquid nozzle 120 is provided on a nozzle support 121 such as an arm. The nozzle support 121 can be moved in the vertical direction by a driving mechanism (not shown) as indicated with a reciprocation arrow A illustrated by a dashed line in the drawing and can be moved in the horizontal direction as indicated with a reciprocation arrow B illustrated by a dashed line. The developing liquid nozzle 120 is connected to a developing liquid source 123 via a supply pipe 122.

Further, in the processing vessel 110, a first cleaning liquid nozzle 130 as a first cleaning liquid supply is provided. The first cleaning liquid nozzle 130 is configured to discharge a first cleaning liquid toward the front surface of the wafer W. The first cleaning liquid nozzle 130 is provided on a nozzle support 131 such as an arm. The nozzle support 131 can be moved in the vertical direction by a driving mechanism (not shown) as indicated with a reciprocation arrow C illustrated by a dashed line in the drawing and can be moved in the horizontal direction as indicated with a reciprocation arrow D illustrated by a dashed line. The first cleaning liquid nozzle 130 is connected to a first cleaning liquid source 133 via a supply pipe 132.

In the developing liquid supply apparatus 30 according to the present exemplary embodiment, while the wafer W is rotated, the developing liquid or the first cleaning liquid is supplied to the center of the wafer W to diffuse the developing liquid or the first cleaning liquid over the entire wafer W.

The supply method of the developing liquid or the first cleaning liquid is not particularly limited as long as the developing liquid or the first cleaning liquid can be supplied onto the front surface of the wafer W. That is, the configuration of the developing liquid supply apparatus 30 is appropriately changed depending on a developing method to be employed such as a puddle development or a spray development. Further, for example, the cleaning liquid supply apparatus 32 may be equipped with the first cleaning liquid nozzle 130, and the wafer W may be transferred into the cleaning liquid supply apparatus 32 and then supplied with the first cleaning liquid.

### <Cleaning Liquid Supply Apparatus>

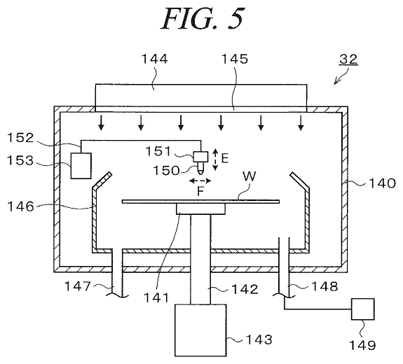

FIG. 5 is a longitudinal cross-sectional view schematically illustrating a configuration of the cleaning liquid supply apparatus 32 according to the exemplary embodiment. The cleaning liquid supply apparatus 32 has a housing 140, and a carry-in/out port (not shown) for the wafer W is provided at a side surface of the housing 140. In the housing 140, a spin chuck 141 is provided as a substrate holder. The spin chuck 141 horizontally holds the wafer W, and is connected to a rotator 142 movable in the vertical direction. The rotator 142 is connected to a rotation driver 143 composed of a motor or the like. Accordingly, the wafer W held on the spin chuck 141 is rotated by operating the rotation driver 143.

At a ceiling portion of the housing 140, a filter device 144 is provided. Air purified by the filter device 144 is supplied into the housing 140 via an air supply 145, and a downflow of the purified air is formed in the housing 140.

A cup 146 is provided around the spin chuck 141. The cup 146 is configured to receive and collect a liquid scattered or dropped from the wafer W. At a bottom of the cup 146, a drain pipe 147 and an exhaust pipe 148 are provided. The exhaust pipe 148 leads to an exhaust device 149 such as an exhaust pump.

In the housing 140, a second cleaning liquid nozzle 150 as a second cleaning liquid supply is provided. The second cleaning liquid nozzle 150 is configured to discharge a second cleaning liquid toward the front surface of the wafer W. The second cleaning liquid nozzle 150 is provided on a nozzle support 151 such as an arm. The nozzle support 151 can be moved in the vertical direction by a driving mechanism (not shown) as indicated with a reciprocation arrow E illustrated by a dashed line in the drawing and can be moved in the horizontal direction as indicated with a reciprocation arrow F illustrated by a dashed line. The second cleaning liquid nozzle 150 is connected to a second cleaning liquid source 153 via a supply pipe 152.

In the cleaning liquid supply apparatus 32 according to the present exemplary embodiment, while the wafer W is rotated, the second cleaning liquid is supplied to the center of the wafer W to diffuse the second cleaning liquid over the entire wafer W. The supply method of the cleaning liquid is not particularly limited as long as the second cleaning liquid can be supplied onto the front surface of the wafer W. That is, the configuration of the cleaning liquid supply apparatus 32 is not limited to the configuration explained in the present exemplary embodiment.

### <Thermal Processing Apparatus>

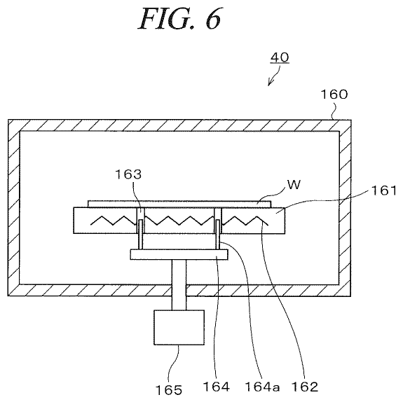

FIG. 6 is a longitudinal cross-sectional view schematically illustrating a configuration of the thermal processing apparatus 40 according to the exemplary embodiment. The thermal processing apparatus 40 has a processing vessel 160, and a carry-in/out port (not shown) for the wafer W is provided at a side surface of the processing vessel 160. In the processing vessel 160, a stage 161 is provided as a substrate holder on which the wafer W is placed. A heater 162 configured to heat the wafer W is provided in the stage 161. Also, through holes 163 are formed at a plurality of locations in the stage 161. Elevating pins 164a configured to respectively elevate inside the through holes 163 are fixed to an elevating pin support 164. The elevating pin support 164 is elevated in the vertical direction by an elevating mechanism 165.

Note that the thermal processing apparatus 40 is not limited to the configuration explained in the present exemplary embodiment but only needs to have a configuration capable of heating the wafer W.

### <Ultraviolet Radiation Apparatus>

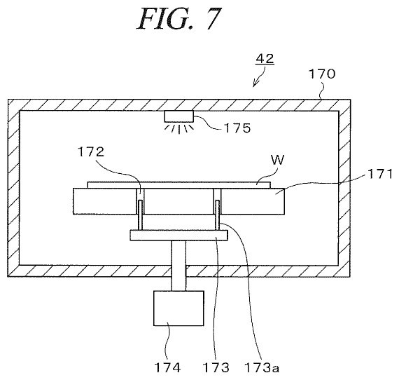

FIG. 7 is a longitudinal cross-sectional view schematically illustrating a configuration of the ultraviolet radiation apparatus 42 according to the present exemplary embodiment. The ultraviolet radiation apparatus 42 has a housing 170, and a carry-in/out port (not shown) for the wafer W is provided at a side surface of the housing 170. In the housing 170, a stage 171 is provided as a substrate holder on which the wafer W is placed. Also, through holes 172 are formed at a plurality of locations in the stage 171. Elevating pins 173a configured to respectively elevate inside the through holes 172 are fixed to an elevating pin support 173. The elevating pin support 173 is elevated in the vertical direction by an elevating mechanism 174.

Above the stage 171, a UV lamp 175 as an ultraviolet radiator is provided. The UV lamp 175 radiates ultraviolet light to the front surface of the wafer W placed on the stage 171. The UV lamp 175 radially radiates ultraviolet light having a wavelength of 190 nm to 400 nm. For example, a KrF exposure apparatus configured to radiate ultraviolet light having a wavelength of 248 nm is used as the ultraviolet radiation apparatus 42. The ultraviolet radiation apparatus 42 is not particularly limited as long as it has a configuration capable of radiating the ultraviolet light having the wavelength of 190 nm to 400 nm.

The substrate processing system 1 according to the present exemplary embodiment has been described above.

### (Developing Method)

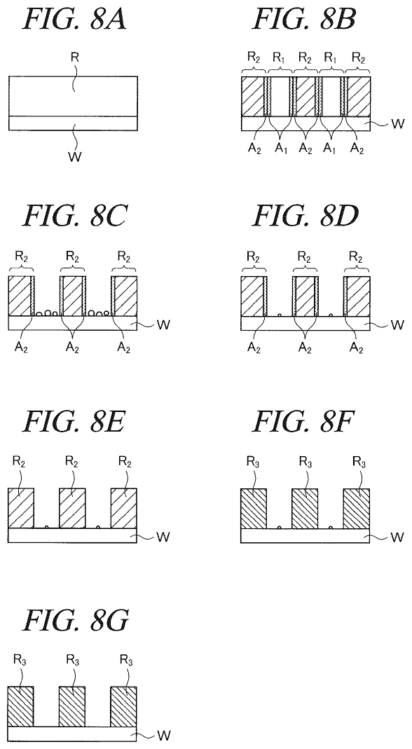

Hereinafter, the developing method for the wafer W using the substrate processing system 1 will be described. FIG. 8A to FIG. 8G are explanatory diagrams illustrating states of a resist film on a wafer during respective processes of the developing method according to the present exemplary embodiment.

First, as shown in FIG. 8A, when a development processing is performed on the wafer W, a metal-containing resist film R is formed on the front surface of the wafer W in the resist coating apparatus.

Then, the “wafer” W is subjected to a periphery exposure processing in the periphery exposure apparatus 41, an exposure processing in the exposure apparatus 12, and a PEB processing in the thermal processing apparatus 40. Thus, as shown in FIG. 8B, the resist film formed on the surface of the wafer W is brought into a state in which an unexposed resist film (hereinafter referred to as “unexposed resist film R₁”) and an exposed resist film (hereinafter referred to as “exposed resist film R₂”) coexist. Therefore, the resist film is exposed into a predetermined pattern. Further, the predetermined pattern is appropriately set depending on semiconductor product specifications.

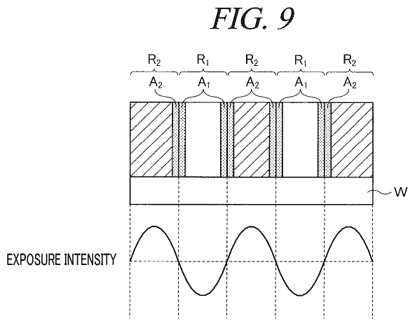

However, as shown in FIG. 9, during the exposure processing, the exposure is performed in a state where exposure intensity periodically changes due to characteristics of the exposure apparatus. Accordingly, in the unexposed resist film R₁, the exposure intensity in a central region sufficiently distant from a boundary with the exposed resist film R₂ is low such that the polymerization reaction does not proceed, whereas the exposure intensity in a region near the boundary with the exposed resist film R₂ is higher than that in the central region of the unexposed resist film R₁.

Accordingly, in the central region of the unexposed resist film R₁, no polymerization reaction occurs. However, in the region, near the boundary with the exposed resist film R₂, of the unexposed resist film R₁, a slight polymerization reaction proceeds, so that an intermediate polymer is formed. In the following description, the region of the unexposed resist film R₁ in which the intermediate polymer is formed is referred to as “region A₁.”

Meanwhile, as described above, the exposure intensity periodically changes. Thus, in the exposed resist film R₂, a central region sufficiently distant from a boundary with the unexposed resist film R₁ is exposed at an intensity sufficient for the polymerization reaction to proceed. However, in the exposed resist film R₂, the exposure intensity in a region near the boundary with the unexposed resist film R₁ is lower than that in the central region of the exposed resist film R₂.

Accordingly, in the central region of the exposed resist film R₂, the polymerization reaction sufficiently proceeds, whereas in the region, near the boundary with the unexposed resist film R₁, of the exposed resist film R₂, the polymerization reaction proceeds insufficiently so that an intermediate polymer is formed. In the following description, the region of the exposed resist film R₂ in which the intermediate polymer is formed is referred to as “region A₂.” Then, as shown in FIG. 8C, the wafer W exposed into the predetermined pattern is transferred to the developing liquid supply apparatus 30, and a developing liquid containing an organic solvent is supplied to the front surface of the wafer W. As a result, the unexposed resist film R₁ formed on the front surface of the wafer W is dissolved.

The type of organic solvent contained in the developing liquid is not particularly limited as long as it dissolves the unexposed resist film R₁ without dissolving the exposed resist film R₂. The developing liquid may also be a mixed liquid of two or more organic solvents. For example, a mixed liquid of PGMEA (propylene glycol monomethyl ether acetate) and acetic acid may be employed as the developing liquid.

When pure water is contained in the developing liquid, it is desirable that the pure water content in the developing liquid is less than 0.25%. When the pure water content in the developing liquid is less than 0.25%, narrowing of the resist pattern can be suppressed. When the pure water content in the developing liquid is 0.25% or more, the solubility for the exposed resist film R₂ in the developing liquid increases so that the resist pattern may be narrowed. Therefore, countermeasures may be required, such as increasing the exposure intensity of the exposure apparatus during the exposure processing prior to development.

Meanwhile, as described above, the unexposed resist film R₁ includes the region A₁ in which the intermediate polymer is formed. The intermediate polymer formed in the region A₁ is less soluble in the developing liquid than the central region of the unexposed resist film R₁. Accordingly, in the process of supplying the developing liquid to the wafer W as shown in FIG. 8C, a part of the intermediate polymer formed in the region A₁ may not be dissolved in the developing liquid and residue such as resist scum may remain on the front surface of the wafer W.

In order to remove the residue, in a subsequent process, the first cleaning liquid is supplied to the front surface of the wafer W. The first cleaning liquid contains an organic solvent and 0.25 to 50 vol % pure water, and has a lower solubility for the metal-containing resist film than the developing liquid in order to avoid dissolving the resist pattern.

The term “solubility for the metal-containing resist film” refers to an index indicating the ease with which the metal-containing resist film dissolves in the processing liquid such as the developing liquid or the first cleaning liquid. For example, in evaluating the solubility of two kinds of processing liquids, an equal amount of each of the two processing liquids is supplied to the metal-containing resist films having the same composition, and the dissolution amount of the resist film (volume reduction) per unit time is compared. Among the two processing liquids, the one liquid with the smaller dissolution amount of the resist film per unit time is considered to have the lower solubility for the metal-containing resist film than the other liquid.

The developing liquid has solubility such that the exposed resist film R₂ is not dissolved, but when a processing liquid having a higher solubility than the developing liquid is used as the first cleaning liquid, the exposed resist film R₂ is dissolved and the pattern shape may collapse.

Further, in the region A₂ existing in the exposed resist film R₂, the polymerization reaction has proceeded less than in the central region of the exposed resist film R₂. Therefore, the region A₂ is more easily dissolved in the organic solvent compared with the central region of the exposed resist film R₂. Accordingly, when the solubility for the metal-containing resist film in the first cleaning liquid is the same as that in the developing liquid, there is concern that the exposed resist film R₂ in the region A₂ may be slightly dissolved, leading to collapse of the pattern shape.

Accordingly, a processing liquid having a lower solubility for the metal-containing resist film than the developing liquid is used as the first cleaning liquid and thus can dissolve the residue remaining on the front surface of the wafer W without dissolving the exposed resist film R₂, as shown in FIG. 8D. That is, it is possible to reduce the amount of residue on the front surface of the wafer W without causing the collapse of the pattern.

The type of organic solvent contained in the first cleaning liquid is not particularly limited as long as it has a lower solubility for the metal-containing resist film than the developing liquid. For example, when the organic solvent contained in the developing liquid is 2-heptanone, MIBC (methyl isobutyl carbinol) or PGMEA (propylene glycol monomethyl ether acetate) which has a lower solubility for the metal-containing resist film than 2-heptanone may be employed as the organic solvent contained in the first cleaning liquid.

If the organic solvent contained in the developing liquid is a mixed liquid of PGMEA and acetic acid, a processing liquid selected from the group consisting of 2-heptanone, IPA (isopropyl alcohol), PGME (propylene glycol monomethyl ether), PGMEA, nBA (n-butyl acetate), cyclohexanone, MIBC, and ethyl lactate, or a mixed liquid of two or more of them may be employed as the organic solvent contained in the first cleaning liquid.

Since pure water contained in the first cleaning liquid is a highly polar solvent, it readily dissolves residue, which is a highly polar substance. Accordingly, by supplying the first cleaning liquid containing 0.25 to 50 vol % pure water to the wafer W, the amount of residue on the front surface of the wafer W can be reduced compared with the case where a cleaning liquid excluding pure water is supplied.

When the pure water content in the first cleaning liquid is less than 0.25 vol %, a sufficient residue-dissolving capability cannot be obtained.

When the pure water content in the first cleaning liquid is 50 vol % or more, the properties of the pure water primarily determine the wettability of the first cleaning liquid and the contact angle of the first cleaning liquid with respect to the wafer W and the exposed resist film R₂ increases. As a result, after the first cleaning liquid is supplied, droplets are likely to form on the front surfaces of the wafer W and the exposed resist film R₂, and splashing accompanied by the rotation of the wafer W is more likely to occur, which may cause contamination inside the module.

Further, the exposed portions and the unexposed portions are present on the front surface of the wafer W. Thus, regions having different wettability coexist. When the pure water content in the first cleaning liquid is 50 vol % or more and the contact angle of the first cleaning liquid increases, a difference in contact angle between the regions having different wettability increases. A liquid present in a region of a smaller contact angle hardly flows into a region of a relatively larger contact angle. Therefore, when the pure water content in the first cleaning liquid is 50 vol % or more, it is difficult to remove the first cleaning liquid from the wafer W even by rotating the wafer W.

For these reasons, the pure water content in the first cleaning liquid is limited to 0.25 vol % to 50 vol %.

Among the organic solvents that can be used as the first cleaning liquid, for example, IPA or PGME is highly hydrophilic and readily mixes with pure water. Meanwhile, organic solvents, such as 2-heptanone, PGMEA, and nBA, are less hydrophilic than IPA and PGME, and thus tend to separate from pure water.

Accordingly, when an organic solvent having low hydrophilicity, such as 2-heptanone, PGMEA, or nBA, is used as the organic solvent contained in the first cleaning liquid, it is desirable to mix a hydrophilic organic solvent such as IPA or PGME. As a result, a hydrophilic organic solvent, such as IPA or PGME, promotes mixing of a less hydrophilic organic solvent, such as 2-heptanone, PGMEA, or nBA, with pure water. Even when a less hydrophilic organic solvent is used, the first cleaning liquid sufficiently mixed with pure water can be prepared.

The developing method according to the present exemplary embodiment has been explained above. According to this developing method, by performing the process of supplying the first cleaning liquid to the wafer W after supplying the developing liquid to the wafer W, a predetermined resist pattern can be formed while reducing the residue that is not dissolved by the developing liquid and remains on the front surface of the wafer W.

### (Cleaning With Second Cleaning Liquid)

In order to further reduce the amount of residue remaining on the front surface of the wafer W, the following process is performed as needed after the process of supplying the first cleaning liquid to the wafer W.

First, the wafer W cleaned with the cleaning liquid is transferred to the ultraviolet radiation apparatus 42, and ultraviolet light having a wavelength of 190 nm to 400 nm is radiated to the front surface of the wafer W. In this process, for example, KrF having a wavelength of 248 nm is radiated. During the radiation of ultraviolet light, no mask is used and the ultraviolet light is uniformly radiated to the entire wafer W. Therefore, as shown in FIG. 8E, the exposure reaction further proceeds in the entire exposed resist film R₂, and the exposure reaction also proceeds in the region A₂ of the resist film R₂, where the exposure reaction has proceeded less, in the same manner as in the other regions.

When the wavelength of the ultraviolet light is less than 190 nm, a reaction in which C—O bonds of the resist film R₂ are cleaved occurs due to the radiation of the ultraviolet light, but the exposure reaction of the resist film R₂ does not occur. In the present exemplary embodiment, the radiation of ultraviolet light is performed by the ultraviolet radiation apparatus 42, but may also be performed by, for example, the exposure apparatus 12.

Next, the wafer W radiated with the ultraviolet light is transferred to the thermal processing apparatus 40 and heated. As a result, as shown in FIG. 8F, the polymerization reaction of the exposed resist film R₂is further promoted, and thus, the resist film R₂ is cured and transformed into a hardened resist film R₃.

In the present exemplary embodiment, heating of the wafer W after the radiation of ultraviolet is performed by the thermal processing apparatus 40. However, for example, if the ultraviolet radiation apparatus 42 includes a heating mechanism for the wafer W, the wafer W may be heated in the ultraviolet radiation apparatus 42. Further, when the radiation of ultraviolet light and the heating of the wafer W can be performed in the same module, the wafer W may be heated during the radiation of ultraviolet light, or may be heated after the radiation of ultraviolet light.

Thereafter, the heated wafer W is transferred to the cleaning liquid supply apparatus 32, and a second cleaning liquid is supplied to the front surface of the wafer W. Since the second cleaning liquid contains an organic solvent, the residue on the front surface of the wafer W is dissolved upon contact with the second cleaning liquid, as shown in FIG. 8G.

Since the resist film R₃ hardened by the radiation of ultraviolet and the heating is hardly dissolved in an organic solvent, a processing liquid having a higher solubility for the resist film than the first cleaning liquid may be used as the second cleaning liquid. Accordingly, the residue, which is not sufficiently removed in the process of cleaning the wafer W with the first cleaning liquid as shown in FIG. 8D, can be dissolved. Thus, it is possible to further reduce the amount of residue on the front surface of the wafer W.

The organic solvent contained in the second cleaning liquid is not particularly limited as long as it has a solubility insufficient to dissolve the hardened resist film R₃. Alternatively, it may be a mixed liquid of two or more types of organic solvents. Examples of the organic solvent contained in the second cleaning liquid include an alkaline processing liquid containing TMAH (tetramethylammonium hydroxide), or a processing liquid containing an organic acid such as acetic acid, formic acid, or citric acid.

In the present exemplary embodiment, the second cleaning liquid is supplied to the wafer W by the cleaning liquid supply apparatus 32. However, when the developing liquid supply apparatus 30 has a function of supplying the second cleaning liquid, the second cleaning liquid may be supplied by the developing liquid supply apparatus 30.

The second cleaning liquid may also be selected based on a difference in solubility caused by the polarity difference from the first cleaning liquid. For example, when the pure water content in the first cleaning liquid is low, the second cleaning liquid having a higher polarity than the first cleaning liquid may be used. As such, by selecting the second cleaning liquid based on its polarity difference from the first cleaning liquid, the solubility for the metal-containing resist film can be changed, and the possibility of residue remaining on the front surface of the wafer W can be further reduced.

After the cleaning of the wafer W with the second cleaning liquid is completed, cleaning of the wafer W with pure water and drying are performed. As a result, a series of development processes is completed.

As described above, by radiating the ultraviolet light with the wavelength of 190 nm to 400 nm to the wafer W after supplying the developing liquid, then heating the wafer W, and subsequently supplying the second cleaning liquid to the wafer W, the dissolution of residue on the front surface of the wafer W can be promoted, and the amount of residue can be further reduced.

In the exemplary embodiment described above, the organic solvent and pure water are mixed in the source 133 shown in FIG. 4 in advance, and the mixed liquid as the first cleaning liquid is supplied to the wafer W. However, the method of supplying the first cleaning liquid containing in advance organic solvent and in advance pure water to the wafer W according to the present disclosure is not limited to the exemplary embodiment shown in FIG. 4.

For example, the type of “supplying the first cleaning liquid containing the organic solvent and the pure water to the wafer W” may be implemented such that pure water may be added and mixed in a flow path (organic solvent flow path) extending from an organic solvent source to a discharge port of a nozzle for discharging the organic solvent. In this case, for example, a pure water supply pipe (not shown) is connected to an organic solvent supply pipe and pure water is supplied from the pure water supply pipe. Thus, the organic solvent and the pure water are mixed to prepare the first cleaning liquid.

As another example, the type of “supplying the first cleaning liquid containing the organic solvent and the pure water to the wafer W” may be implemented such that the organic solvent may be supplied to the front surface of the wafer W and then, the pure water may be supplied to the organic solvent remaining on the front surface of the wafer W to mix them. In this case, for example, an organic solvent nozzle for discharging the organic solvent and a pure water nozzle for discharging pure water are separately provided. After the organic solvent is discharged to the wafer W from the organic solvent nozzle, the pure water may be discharged toward the wafer W from the pure water nozzle to mix the organic solvent and the pure water on the front surface of the wafer W. As another example, above the wafer W, the pure water may be sprayed toward the wafer W from a shower head having a plurality of openings to mix the pure water with the organic solvent remaining on the front surface of the wafer W. When the pure water is supplied to the organic solvent remaining on the front surface of the wafer W, the first cleaning liquid containing both the organic solvent and the pure water is present on the front surface of the wafer W. Thus, it can be substantially regarded that the first cleaning liquid containing the organic solvent and the pure water has been supplied to the wafer W. That is, the example described in this paragraph also falls within the technical scope of the present disclosure.

The first cleaning liquid according to the present disclosure contains 0.25 to 50 vol % pure water. However, the present inventors have found that as the pure water content increases, the metal-containing resist film may deteriorate due to the chemical reaction between the organic solvent and the pure water, depending on the type of organic solvent. Therefore, the pure water content in the first cleaning liquid is desirably, for example, 0.25 vol % to 10 vol %. As a result, it is possible to reduce the possibility of deterioration of process performance or occurrence of defects caused by the deterioration of the metal-containing resist film.

Further, when the pure water is sprayed onto the wafer W, the amount of pure water supplied relative to the supply time can be set to be much smaller than in the case where the pure water is discharged from a nozzle. Therefore, it becomes easy to prepare the first cleaning liquid containing 0.25 to 10 vol % pure water. Further, by spraying the pure water, the first cleaning liquid having a uniform distribution of the pure water content on the front surface of the wafer W can be prepared in a short time. The expression “preparing the first cleaning liquid on the front surface of the wafer” as described above corresponds to “supplying the first cleaning liquid containing the organic solvent and pure water onto the wafer W”, since it allows a state in which the first cleaning liquid containing the organic solvent and the pure water is present on the front surface of the wafer W to be realized.

Further, the expression “supplying the first cleaning liquid containing the organic solvent and pure water onto the wafer W” may include a type of supplying the pure water only to a partial region including the center of the wafer W after the completion of development by supplying the developing liquid. In this case, the pure water is supplied simultaneously with a timing at which a liquid remaining on the front surface of the wafer W begins to be drained outward by increasing the rotational frequency of the wafer W or before a timing of increasing the rotational frequency of the wafer W. Also, the pure water may be further supplied to the partial region after the first cleaning liquid is prepared by supplying the pure water to the organic solvent remaining on the front surface of the wafer W. Herein, the term “partial region” refers to a region radially inward of a peripheral portion of the liquid remaining on the front surface of the wafer W. That is, by further supplying the pure water to the partial region after the preparation of the first cleaning liquid, a region having a high contact angle is formed radially inward of the peripheral portion of the liquid remaining on the front surface of the wafer W. As a result, when the wafer W is subsequently rotated to drain the liquid remaining on its front surface outward, the liquid in the region having the high contact angle pushes outward a liquid located radially outside the region, which enables efficient drainage from the front surface of the wafer W.

Note that the developing method for the substrate according to the present disclosure is also applicable to a developing method for a processing target substrate other than the semiconductor wafer, for example, an FPD (flat panel display) substrate.

The exemplary embodiments disclosed herein are illustrative in all aspects and do not limit the present disclosure. The above exemplary embodiments can be embodied in various forms. Further, the above-described exemplary embodiments may be omitted, substituted, or changed in various forms without departing from scope of the appended claims, the configuration examples included in the technical scope of the present disclosure to be described later and the gist thereof. For example, the constituent elements of the above-described exemplary embodiments may be combined in various ways. From any of these various combinations, functions and effects for the respective constituent elements are naturally obtained, and other functions and other effects obvious to a person with ordinary skill in the art are also obtained from the description of the present disclosure.

Further, the effects described in the present disclosure are only explanatory or illustrative and are not limiting. That is, the technique according to the present disclosure may exhibit, together with or instead of the above-described effects, other effects obvious to a person with ordinary skill in the art from the description of the present disclosure.

The example configurations described below may also fall within the technical scope of the present disclosure.

(1) A developing method of performing a development processing on a substrate, the developing method including:
supplying a developing liquid containing an organic solvent to the substrate having a metal-containing coating film exposed into a predetermined pattern; and
supplying a first cleaning liquid containing an organic solvent to the substrate supplied with the developing liquid,
wherein the first cleaning liquid has a lower solubility for the metal-containing coating film than the developing liquid and contains 0.25 to 50 vol % pure water.

(2) The developing method described in (1),
wherein the organic solvent contained in the first cleaning liquid is one selected from a group consisting of 2-heptanone, isopropyl alcohol, propylene glycol monomethyl ether, propylene glycol monomethyl ether acetate, n-butyl acetate, cyclohexanone, methyl isobutyl carbinol, and ethyl lactate, or is a mixed liquid of two or more thereof.

(3) The developing method described in (1) or (2),
wherein the developing liquid is a mixed liquid of propylene glycol monomethyl ether and acetic acid.

(4) The developing method described in any one of (1) to (3),
wherein the pure water contained in the developing liquid is less than 0.25 vol %.

(5) The developing method described in any one of (1) to (4),
radiating ultraviolet light having a wavelength of 190 nm to 400 nm to the substrate supplied with the first cleaning liquid;
heating the substrate during or after the radiating of the ultraviolet light; and supplying a second cleaning liquid containing an organic solvent to the heated substrate.

(6) The developing method described in (5),
wherein the second cleaning liquid is a processing liquid containing an alkaline processing liquid or an organic acid.

(7) A substrate processing system configured to perform a development processing on a substrate, the substrate processing system including:
a developing liquid supply configured to supply a developing liquid containing an organic solvent to the substrate;
a first cleaning liquid supply configured to supply a first cleaning liquid containing an organic solvent to the substrate; and
a controller configured to control operations of the developing liquid supply and the first cleaning liquid supply,
wherein the controller is configured to perform: supplying the developing liquid to the substrate having a metal-containing coating film exposed into a predetermined pattern; and
supplying the first cleaning liquid to the substrate supplied with the developing liquid, and
the first cleaning liquid has a lower solubility for the metal-containing coating film than the developing liquid and contains 0.25 to 50 vol % pure water.

(8) The substrate processing system described in (7),
wherein the organic solvent contained in the first cleaning liquid is one selected from a group consisting of 2-heptanone, isopropyl alcohol, propylene glycol monomethyl ether, propylene glycol monomethyl ether acetate, n-butyl acetate, cyclohexanone, methyl isobutyl carbinol, and ethyl lactate, or is a mixed liquid of two or more thereof.

(9) The substrate processing system described in (7) or (8),
wherein the developing liquid is a mixed liquid of propylene glycol monomethyl ether and acetic acid.

(10) The substrate processing system described in any one of (7) to (9),
wherein the pure water contained in the developing liquid is less than 0.25 vol %.

(11) The substrate processing system described in any one of (7) to (10), further including:
an ultraviolet radiator configured to radiate ultraviolet light having a wavelength of 190 nm to 400 nm to the substrate;
a heater configured to heat the substrate; and
a second cleaning liquid supply configured to supply a second cleaning liquid containing an organic solvent to the heated substrate,
wherein the controller is configured to perform:
radiating the ultraviolet light having the wavelength of 190 nm to 400 nm to the substrate supplied with the first cleaning liquid;
heating the substrate during or after the radiating of the ultraviolet light; and
supplying the second cleaning liquid to the heated substrate.

(12) The substrate processing system described in (11),
wherein the second cleaning liquid is a processing liquid containing an alkaline processing liquid or an organic acid.

### EXPLANATION OF CODES

1: Substrate processing system
30: Developing liquid supply apparatus
32: Cleaning liquid supply apparatus
200: Controller
R: Metal-containing resist film
W: Wafer

We claim:

1. A developing method of performing a development processing on a substrate, the developing method comprising:
supplying a developing liquid containing an organic solvent to the substrate having a metal-containing coating film exposed into a predetermined pattern; and
supplying a first cleaning liquid containing an organic solvent to the substrate supplied with the developing liquid,
wherein the first cleaning liquid has a lower solubility for the metal-containing coating film than the developing liquid and contains 0.25 to 50 vol % pure water.

2. The developing method of claim 1,
wherein the organic solvent contained in the first cleaning liquid is one selected from a group consisting of 2-heptanone, isopropyl alcohol, propylene glycol monomethyl ether, propylene glycol monomethyl ether acetate, n-butyl acetate, cyclohexanone, methyl isobutyl carbinol, and ethyl lactate, or is a mixed liquid of two or more thereof.

3. The developing method of claim 2,
wherein the developing liquid is a mixed liquid of propylene glycol monomethyl ether and acetic acid.

4. The developing method of any one of claims 1 to 3,
wherein the pure water contained in the developing liquid is less than 0.25 vol %.

5. The developing method of any one of claims 1 to 3, further comprising:
radiating ultraviolet light having a wavelength of 190 nm to 400 nm to the substrate supplied with the first cleaning liquid;
heating the substrate during or after the radiating of the ultraviolet light; and
supplying a second cleaning liquid containing an organic solvent to the heated substrate.

6. The developing method of claim 5,
wherein the second cleaning liquid is a processing liquid containing an alkaline processing liquid or an organic acid.

7. A substrate processing system configured to perform a development processing on a substrate, the substrate processing system comprising:
a developing liquid supply configured to supply a developing liquid containing an organic solvent to the substrate;
a first cleaning liquid supply configured to supply a first cleaning liquid containing an organic solvent to the substrate; and
a controller configured to control operations of the developing liquid supply and the first cleaning liquid supply,
wherein the controller is configured to perform:
supplying the developing liquid to the substrate having a metal-containing coating film exposed into a predetermined pattern; and
supplying the first cleaning liquid to the substrate supplied with the developing liquid, and
the first cleaning liquid has a lower solubility for the metal-containing coating film than the developing liquid and contains 0.25 to 50 vol % pure water.

8. The substrate processing system of claim 7,
wherein the organic solvent contained in the first cleaning liquid is one selected from a group consisting of 2-heptanone, isopropyl alcohol, propylene glycol monomethyl ether, propylene glycol monomethyl ether acetate, n-butyl acetate, cyclohexanone, methyl isobutyl carbinol, and ethyl lactate, or is a mixed liquid of two or more thereof.

9. The substrate processing system of claim 8,
wherein the developing liquid is a mixed liquid of propylene glycol monomethyl ether and acetic acid.

10. The substrate processing system of any one of claims 7 to 9,
wherein the pure water contained in the developing liquid is less than 0.25 vol %.

11. The substrate processing system of any one of claims 7 to 9, further comprising:
an ultraviolet radiator configured to radiate ultraviolet light having a wavelength of 190 nm to 400 nm to the substrate;
a heater configured to heat the substrate; and
a second cleaning liquid supply configured to supply a second cleaning liquid containing an organic solvent to the heated substrate,
wherein the controller is configured to perform:
radiating the ultraviolet light having the wavelength of 190 nm to 400 nm to the substrate supplied with the first cleaning liquid;
heating the substrate during or after the radiating of the ultraviolet light; and
supplying the second cleaning liquid to the heated substrate.

12. The substrate processing system of claim 11, wherein the second cleaning liquid is a processing liquid containing an alkaline processing liquid or an organic acid.
